(19) United States
(12) Patent Application Publication
(10) Pub. No.: US 2024/0279801 A1
(43) Pub. Date: Aug. 22, 2024

(54) PRECURSOR DELIVERY SYSTEM WITH SELECTIVE FILTRATION AND METHOD OF USING SAME

(71) Applicant: Eugenus, Inc., San Jose, CA (US)

(72) Inventors: Chong Jiang, Cupertino, CA (US); Vinay Shankar Vidyarthi, Fremont, CA (US); H. William Lucas, JR., Santa Cruz, CA (US); Jose A. Palencia, San Jose, CA (US); Francisco Z. Araiza, San Jose, CA (US)

(21) Appl. No.: 18/441,940

(22) Filed: Feb. 14, 2024

Related U.S. Application Data
(60) Provisional application No. 63/485,851, filed on Feb. 17, 2023.

(51) Int. Cl. C23C 16/44; B01D 46/00; B01D 46/84; C23C 16/455

(52) U.S. Cl. CPC C23C 16/4402; B01D 46/0087; B01D 46/84; C23C 16/4408; C23C 16/45544; B01D 2273/10

(57) ABSTRACT

The disclosed technology relates generally to semiconductor manufacturing, and more particularly to precursor delivery in cyclic deposition. In one aspect, a thin film deposition system comprises a thin film deposition chamber configured to deposit a thin film. The thin film system additionally comprises a precursor source connected to the thin film deposition chamber by a precursor delivery line, wherein the precursor delivery line comprises a filter connected to the precursor source via a first valve, and a by-pass line connected to the precursor source via a second valve.

### CROSS-REFERENCE TO RELATED APPLICATION

Any and all applications for which a foreign or domestic priority claim is identified in the Application Data Sheet as filed with the present application are hereby incorporated by reference under 37 CFR 1.57, and Rules 4.18 and 20.6. This application claims priority to U.S. Provisional Application No. 63/485,851, entitled “PRECURSOR DELIVERY SYSTEM WITH SELECTIVE FILTRATION AND METHOD OF USING SAME,” and filed on Feb. 17, 2023, which is incorporated by reference in its entirety herein.

### BACKGROUND

### Field of the Invention

The disclosed technology relates generally to semiconductor manufacturing, and more particularly to precursor delivery in cyclic deposition.

### Description of the Related Art

As semiconductor devices continue to scale in lateral dimensions, there is a corresponding scaling of vertical dimensions of the semiconductor devices, including thickness scaling of the functional thin films such as electrodes and dielectrics. Semiconductor fabrication involves various thin films that are deposited throughout the process flow. Various thin films can be deposited using different techniques, including dry deposition methods. Dry deposition methods include physical vapor-based techniques, e.g., physical vapor deposition (PVD) and evaporation. Dry deposition methods additionally include precursor and/or chemical reaction-based techniques, e.g., chemical vapor deposition (CVD) and cyclic deposition such as atomic layer deposition (ALD). Dry deposition methods can use various precursor types, including vapor, liquid and solid precursor sources. The precursor sources can sometimes cause the creation of particle defects to be deposited on the substrate, e.g., in the semiconductor film. As the technology node scales to smaller feature sizes, particle defect size and defect count can become increasingly critical in limiting device yield. Particle sources can include various components of the deposition system, precursor cluster, and condensate particle, to name a few, among other sources. Therefore, there is a need for apparatuses and methods for reducing particle defects in thin film deposition.

### SUMMARY

In a first aspect, a precursor delivery system for depositing a thin film in a thin film deposition chamber is disclosed. The precursor delivery system comprises a precursor delivery line comprising a selective filtration portion configured to flow a precursor therethrough, wherein the selective filtration portion is configured to selectively capture particles contained in the precursor flowing therethrough while bypassing gases other than the precursor flowing therethrough.

In a second aspect, a precursor delivery system for depositing a thin film in a thin film deposition chamber is disclosed. The precursor delivery system comprises a precursor delivery line comprising a selective filtration portion; and the selective filtration portion comprising two parallel branches splitting from an inlet and remerging into an outlet connected to the thin film deposition chamber, wherein one but not the other of the two parallel branches comprises a particle filtration zone configured to capture particles contained in a gas flowing therethrough.

In a third aspect, a precursor delivery system for a thin film deposition system is disclosed. The precursor delivery system comprises a precursor delivery line comprising a selective filtration portion; and the selective filtration portion comprising two parallel branches, wherein one of the two parallel branches is configured to selectively flow a precursor through a particle filtration zone, while the other of the two parallel branches is configured to selectively flow an inert gas.

In a fourth aspect, a precursor delivery system for depositing a thin film in a thin film deposition chamber is disclosed. The precursor delivery system comprises a precursor delivery line comprising a selective filtration portion; the selective filtration portion comprising a particle filtration zone configured to capture particles contained in a gas flowing therethrough in a first flow direction; and a purge gas delivery line configured to flow a purge gas through the particle filtration zone in a second flow direction opposite the first flow direction to at least partly release the particles captured in the particle filtration zone.

In a fifth aspect, a precursor delivery system for depositing a thin film in a thin film deposition chamber is disclosed. The precursor delivery system comprises a precursor delivery line comprising a selective filtration portion; and the selective filtration portion comprising a particle filtration zone configured to capture particles contained in a gas flowing therethrough, wherein the particle filtration zone is configured to be heated to at least partly release the particles captured in the particle filtration zone.

In a sixth aspect, a thin film deposition system is disclosed. The thin film deposition system comprises a thin film deposition chamber configured to deposit a thin film; a precursor delivery system according to any one of the above aspects comprising the precursor delivery line connected to a precursor source and comprising the selective filtration portion comprising a filter.

In a seventh aspect, a method of depositing a thin film is disclosed. The method comprises providing a thin film deposition system comprising a thin film deposition chamber and a precursor delivery system according to any one of the first to the fifth aspects, wherein the selective filtration zone of the precursor delivery line comprises two parallel branches comprising a particle filtration branch comprising a particle filtration zone, access to which is controlled by a first valve, and a bypass branch, access to which is controlled by a second valve; and exposing a substrate in the thin film deposition chamber to a precursor by opening the first valve while the second valve is closed, such that the precursor flows selectively through the particle filtration branch.

In an eighth aspect, a method of cleaning a filter in a precursor delivery system for thin film deposition is disclosed. The method comprises providing a thin film deposition system comprising a thin film deposition chamber and a precursor delivery system according to any one of the first to the fifth aspects, wherein the particle filtration zone of the selective filtration portion is configured to capture particles contained in a gas flowing therethrough in a first flow direction; and flowing a purge gas though the particle filtration zone in a second flow direction opposite to the first flow direction to at least partly release the particles captured in the particle filtration zone.

In a ninth aspect, a method of periodically cleaning a filter in a precursor delivery system for thin film deposition is disclosed.

### BRIEF DESCRIPTION OF THE DRAWINGS

FIG. 1 schematically illustrates a thin film deposition system including a thin film deposition chamber and a precursor delivery system configured with precursor delivery lines configured for selective particle filtration, according to some embodiments.

FIG. 2 schematically illustrates a precursor delivery system with a filter and bypass line according to some embodiments.

FIG. 3 schematically illustrates a precursor delivery system with a filter and bypass line during precursor exposure according to some embodiments.

FIG. 4 schematically illustrates a precursor delivery line with a filter and bypass line during precursor exposure according to some embodiments.

FIG. 5 schematically illustrates a precursor delivery system with a filter and bypass line during gas line purging according to some embodiments.

FIG. 6 schematically illustrates a precursor delivery line with a filter and bypass line during gas line purging according to some embodiments.

FIG. 7 schematically illustrates a precursor delivery system with a filter and bypass line during filter cleaning according to some embodiments.

FIG. 8 schematically illustrates a precursor delivery line with a filter and bypass line during filter cleaning according to some embodiments.

FIG. 9 schematically illustrates another precursor delivery line with a filter and bypass line during filter cleaning according to some embodiments.

FIG. 10A shows a precursor delivery line according to some embodiments.

FIG. 10B shows a precursor delivery line according to some other embodiments.

### DETAILED DESCRIPTION

Cyclic deposition processes such as atomic layer deposition (ALD) processes can provide a relatively conformal thin films on relatively high aspect-ratio (e.g., 2:1) structures with high uniformity and thickness precision. While generally less conformal and uniform compared to ALD, thin films deposited using continuous deposition processes such as chemical vapor deposition (CVD) can provide higher productivity and lower cost. ALD and CVD can be used to deposit a variety of different films including elemental metals, metallic compounds (e.g., TiN, TaN, etc.), semiconductors (e.g., Si, III-V, etc.), dielectrics (e.g., SiO₂, AlN, HfO₂, ZrO₂, etc.), rare-earth oxides, conducting oxides (e.g., IrO₂, etc.), ferroelectrics (e.g., PbTiO₃, LaNiO₃, etc.), superconductors (e.g., YBa₂Cu₃O₇₋ₓ), and chalcogenides (e.g., GeSbTe), to name a few.

Some cyclic deposition processes such as atomic layer deposition (ALD) include alternatingly exposing a substrate to a plurality of precursors to form a thin film. The different precursors can alternatingly at least partly saturate the surface of the substrate and react with each other, thereby forming the thin film in a layer-by-layer fashion. Because of the layer-by-layer growth capability, ALD can enable precise control of the thickness and the composition, which in turn can enable precise control of various properties such as conductivity, conformality, uniformity, barrier properties and mechanical strength. Because of the nature of deposition process in ALD, the precursor delivery systems of ALD deposition systems face unique challenges compared to, e.g., the precursor delivery systems of CVD deposition systems. For example, because the alternating exposures of the substrate to multiple precursors are repeatedly carried out at a relatively high speed and/or at a relatively high frequency, precursor delivery systems or components thereof such as precursor delivery line valves can directly or indirectly pose significant limitations to various aspects of the ALD deposition processes, including precision, throughput, reliability and operating cost thereof. Because deposition of a thin film by ALD may involve from few to as much as thousands of cycles of alternating exposures to different precursors, the numbers, durations and frequencies of the alternating exposures of the substrate to multiple precursors is directly proportional to the throughput. The numbers, durations and frequencies of the exposures can in turn be limited by the precursor delivery system or components thereof, such as precursor delivery line configurations.

Cyclic deposition processes such as a vapor deposition process, for example ALD and CVD, can utilize various precursor delivery systems in order to deposit conformal thin films. The precursor delivery systems can be configured for solid, liquid and vapor precursors. The precursor delivery system for a vapor deposition process may need to be maintained at a certain temperature such that the precursors remain in a vapor state prior to delivery into the reaction chamber. However, some precursor delivery systems can introduce a substantial number of particle defects on the substrate being exposed to the precursors due to the temperature fluctuation, precursor impurity, etc. As the size of semiconductor devices shrinks, particle size and defect density may critically impact device yield in ALD and CVD methods. Although several defect modes are known, particle sources for the production of defects may often be precursor clusters, condensate particles, impurities, etc. For example, a precursor cluster may be formed by a reaction between precursor molecules, condensate particles may be formed by condensation of the precursor molecules in the precursor delivery line or within the reactor system due to the temperature fluctuation of the precursor delivery system, and impurity particles may be introduced by unwanted materials found within the delivery system or the precursors themselves. As another example, a “burp” of precursors may happen as the precursors create a positive pressure within the precursor delivery system when the precursors are initially released from the source into the precursor delivery system after initial fill or refill of the source. Such “burp” may carry particles or clusters of particles into the delivery system as they are not fully vaporized. While some thin film deposition systems use a filter within the precursor delivery system to limit the number of unwanted particles formed within the chamber wafer area, as the filter is used, the filter lifetime limits the productivity of the ALD chamber. In particular, if the filter lifetime is shorter than that of other components or the time needed for processing a certain number of wafers, the filter change timeline may shorten the preventive maintenance cycles, reducing the productivity.

Moreover, increasing the lifetime of a filter may be limited due to the type and material used in filter production. On the one hand, the size of a filter, such as the particle removable size for a filter, should be larger than the molecular size of the precursors used for deposition in order to allow the precursors to pass through the filter. Sometimes, after a plurality of depositions the pores of the filter may start to clog and obstruct the precursor gas flow. The number of cycles may depend on the size of the precursor. In some cases, the filter starts to clog after about 300 cycles, 500 cycles, 800 cycles, 1000 cycles, 1500 cycles, 2000 cycles, etc. On the other hand, the size of the filter may not be too large that particle defects, such as precursor clusters, condensate particles, impurities, may be blown through the filter and enter the deposition chamber, such that the deposited films are contaminated by the particle defects, especially by the end of the precursor source usage in a canister. In some embodiments, the particle removable size for a filter may be larger than about or around 10 nm and the particle size of a precursor may be about 1 nm.

In addition, the lifetime of a filter may be shortened by purging the precursor delivery system. For example, after a preventive maintenance, the precursor delivery system may be dirty and may need to be purged before delivering precursors for production. The filter may be saturated or clogged quickly, sometimes even before running production, which limits the productivity.

Thus, there is a need for improved precursor delivery systems that increase productivity while reducing overall cost and unwanted defect particle size and density.

### A. Thin Film Deposition System

To address the above-mentioned needs among others, a thin film deposition system comprises a precursor delivery system for depositing a thin film in a thin film deposition chamber, and a thin film deposition chamber configured to deposit a thin film by alternatingly exposing a substrate to a plurality of precursors. The thin film deposition system further comprises one or more precursor sources, each of which may be connected to the thin film deposition chamber by a precursor delivery line. The precursor delivery system includes a precursor delivery line comprising a selective filtration portion configured to selectively capture particles contained in the precursor flowing therethrough while bypassing gases other than the precursor flowing therethrough. The selective filtration portion comprising two parallel branches splitting from an inlet and remerging into an outlet connected to the thin film deposition chamber, wherein one but not the other of the two parallel branches comprises a particle filtration zone configured to capture particles contained in a gas flowing therethrough in a first flow direction. As configured, the particle filtration zone includes a particle filter that is advantageously configured to capture particles selectively from the precursor, e.g., during exposure of the substrate to the precursor, while allowing purge gases to be bypassed when the substrate is not being exposed to the precursor or running test wafters, thereby increasing the lifespan of the particle filter.

Further, in addition to the precursor delivery line, the precursor delivery system additionally includes a purge gas delivery line configured to flow a purge gas through the particle filtration zone in a second flow direction opposite the first flow direction to at least partly release the particles captured in the particle filtration zone. As configured, the particle filter can advantageously be restored or cleaned without opening the thin film deposition chamber, especially for large precursor clusters.

As described herein, an atomic layer deposition (ALD) valve refers to a precursor delivery valve configured for introducing a precursor into an ALD deposition chamber in pulses with high precision and speed (e.g., a response time less than 30 ms) while having a high flow coefficient (e.g., Cᵥ exceeding 0.20). Because the deposition of a thin film by ALD may involve from a few to as much as thousands of cycles of alternating exposures to different precursors, valve parameters such as the flow rate, speed and/or frequency of the ALD valves can directly impact the deposition throughput as well as the efficiency of precursor use. In addition, the wear of ALD valves can limit the service life of some ALD systems between preventive maintenance services. Some precursors, which are delivered at elevated temperatures, can further limit the throughput and service life of some ALD systems.

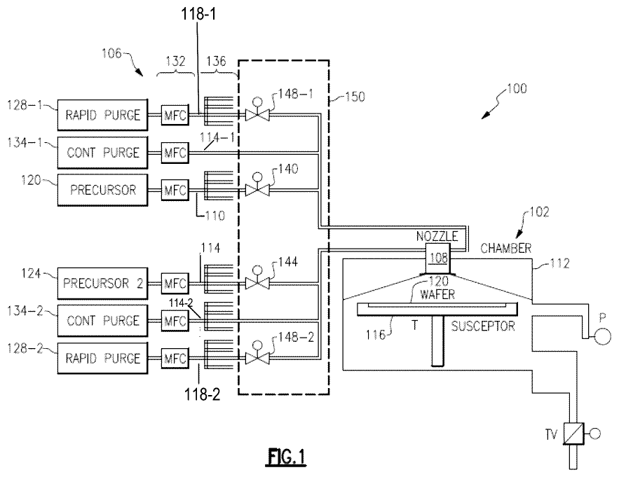

FIG. 1 schematically illustrates an exemplary thin film deposition system including a thin film deposition chamber and a precursor delivery system configured for selective particle filtration, according to some embodiments. Referring to FIG. 1, the thin film deposition system 100 includes a thin film deposition chamber 102 and a precursor delivery system 106 configured to deliver a plurality of precursors into the deposition chamber 102. The illustrated deposition chamber 102 is configured to process a substrate 120, e.g., a wafer, on a support 116, e.g., a susceptor, under a process condition. The deposition chamber 102 additionally includes a nozzle 108 configured to centrally discharge the plurality of precursors into the deposition chamber 102 through a gas distribution plate 112, also referred to as a showerhead. The nozzle 108 may mix gases, e.g., a precursor and a purge gas, prior to being diffused into the deposition chamber 102 by the gas distribution plate 112. The gas distribution plate 112 is configured to uniformly diffuse the precursor(s) over the substrate 120 on the susceptor 116 so that a uniform deposition occurs. The deposition chamber may be equipped with pressure monitoring sensors (P) and/or temperature monitoring sensors (T).

With continued reference to FIG. 1, the precursor delivery system 106 may be configured to deliver a plurality of precursors from precursor sources (120, 124) and one or more purge gases, e.g., inert gases, from purge gas sources (128-1, 128-2, 134-1, 134-2) into the process chamber. Each of the precursors and purge gases may be connected to the deposition chamber 102 by a respective gas delivery line. Advantageously, at least some of the gas delivery lines may comprise increased conductance line portions serving as intermediate gas reservoirs between the precursor or purge gas sources and the thin film deposition chamber 102. The gas delivery lines may additionally include in their paths mass flow controllers (MFCs) 132 and respective precursor valves for introducing respective precursors into the thin film deposition chamber. Further advantageously, at least some of the valves can be atomic layer deposition (ALD) valves. The gas delivery lines are connected to the deposition chamber 102 through the gas distribution plate 112.

The precursor sources (120, 124) can be any of gas, liquid or solid precursor sources, such as canisters, reservoirs or tanks. It will be appreciated that, while not illustrated in FIG. 1, when the precursor sources (120, 124) are liquid or solid precursor sources, carrier gases carrying the vaporized precursors are introduced into the MFCs 132, as described further with respect to subsequent figures.

For illustrative purposes only, in the illustrated configuration of FIG. 1, the plurality of precursors may include a first precursor and a second precursor. The first precursor may be stored in at least one first precursor source 120, and the second precursor may be stored in at least one second precursor source 124. The precursor delivery system 106 may be configured to deliver the first and second precursors from the first and second precursor sources 120, 124 into the deposition chamber 102 through first and second precursor delivery lines 110, 114, respectively. A rapid purge (RP) gas can be stored in at least two RP gas sources 128-1, 128-2. In some embodiments, the RP purge gas may be used to clean the precursor residue collected on inner surfaces of the precursor delivery lines. For example, the RP gas may be turned on after exposing the substrate to a first precursor and before exposing the substrate to a second precursor, such that the second precursor would be free of any contamination from the first precursor gas or any residue thereof remaining in the delivery line, such that the two precursors would be completely separated from each other. In some embodiments, the RP purge gas is always turned on to continuously remove any residues as they form. The precursor delivery system 106 may be configured to deliver the rapid purge (RP) gas from the RP gas sources 128-1, 128-2 into the deposition chamber 102 through respective ones of RP gas delivery lines 118-1, 118-2. A continuous purge (CP) gas can be stored in at least two CP gas sources 134-1, 134-2. In some embodiments, the CP gas is used to control the precursor partial pressure. In some embodiment, the CP gas is turned on throughout the deposition process. The precursor delivery system 106 may be configured to deliver the CP gas from the CP gas sources 134-1, 134-2 into the deposition chamber 102 through respective ones of CP gas delivery lines 114-1, 114-2.

With continued reference to FIG. 1, the first and second precursors may be configured to be delivered from the first and second precursor sources 120, 124, respectively, by independently actuating first and second precursor atomic layer deposition (ALD) valves 140 and 144 that are connected in parallel to the common gas distribution plate 112. Additionally, the RP purge gas may be configured to be delivered from the RP purge gas sources 128-1, 128-2 by independently actuating two respective purge gas atomic layer deposition (ALD) valves 148-1, 148-2 that are connected in parallel to the common gas distribution plate 112. The ALD valves 140, 144, 148-1 and 148-2 and the respective delivery lines connected to the gas distribution plate 112 can be arranged to feed the respective gases into the nozzle 108 through a multivalve block assembly 150, which may be attached to a lid of the deposition chamber 102. In the illustrated configuration in FIG. 1, the ALD valves 140, 144, 148-1 and 148-2 may be the final valves before the respective gases are introduced into the deposition chamber 102.

Under some circumstances, the ALD valves according to embodiments are advantageously configured to be operated at elevated temperatures. For example, when it is desirable for a precursor, e.g., a vaporized liquid precursor, to be introduced into the deposition chamber at an elevated temperature, it may be advantageous for the corresponding ALD valve and/or the multivalve block to be heated to a temperature greater than room temperature, e.g., to match the precursor temperature at the point of introduction into the multivalve block. According to various embodiments, the ALD valves are configured to operate at valve temperature exceeding 80° C., 100° C. 150° C., 200°° C., 250° C. or a temperature in a range defined by any of these values. In some embodiments, the gas lines and the ALD valves are maintained at a temperature higher than the precursor sources. In some embodiments, the gas lines and the ALD valves are maintained at temperatures higher than the temperature of the canister to avoid condensation during the delivery of the precursors. In some embodiments, the temperature gradient of the gas lines and the ALD valves is maintained to be positive in the direction from the precursor sources to the deposition chamber. In some embodiments, cold spot is substantially prevented from being formed along the gas lines and the ALD valves.

B. Precursor Delivery System with Selective Particle Filtration Using a Filter and Parallel Bypass Line

To address the above-mentioned needs, among others, the thin film deposition system may comprise a precursor delivery system includes a selective filtration portion comprising two parallel branches splitting from an inlet and remerging into an outlet connected to the thin film deposition chamber, wherein one but not the other of the two parallel branches comprises a particle filtration zone configured to capture particles contained in a gas flowing therethrough in a first flow direction. In particular, the precursor delivery system comprises a precursor delivery line with a filter and a bypass line that are arranged in parallel. The precursor deliver line includes the particle filtration zone equipped with a filter. In some embodiments, a precursor delivery line may be connected by a first valve to a filter and by a second valve to a parallel bypass line. Both the filter and the bypass line may be connected to a deposition chamber through a common final valve. This configuration may be advantageous for process chambers that use multiple precursors and purges. For instance, in some embodiments, a precursor gas, which needs to be filtered, may be passed through the filter into the chamber. However, purge gases, which may not need to be filtered, e.g., during gas line purge, may alternatively be passed through the bypass line and not through the filter, into the reaction chamber. By avoiding passing all materials and precursors through the filter system, the overall lifetime of the filter may be increased. Advantageously, the use of a filter and a bypass line may also enable the cleaning of the filter. In some embodiments, the valve between the bypass line and the precursor delivery system or foreline pump may be closed. At the same time, the valve between the filter and the foreline pump may be left open. A purge gas may then be pumped in the reverse direction, e.g., through the filter in the opposite direction that the precursor is pumped, thereby removing particles that may be trapped in the filter. In some embodiments, all gasses, including the precursor gasses and purge gases, are filtered before entering the deposition chamber. In some embodiments, the filters for all the gasses can be cleaned similarly as discussed for precursor filtration.

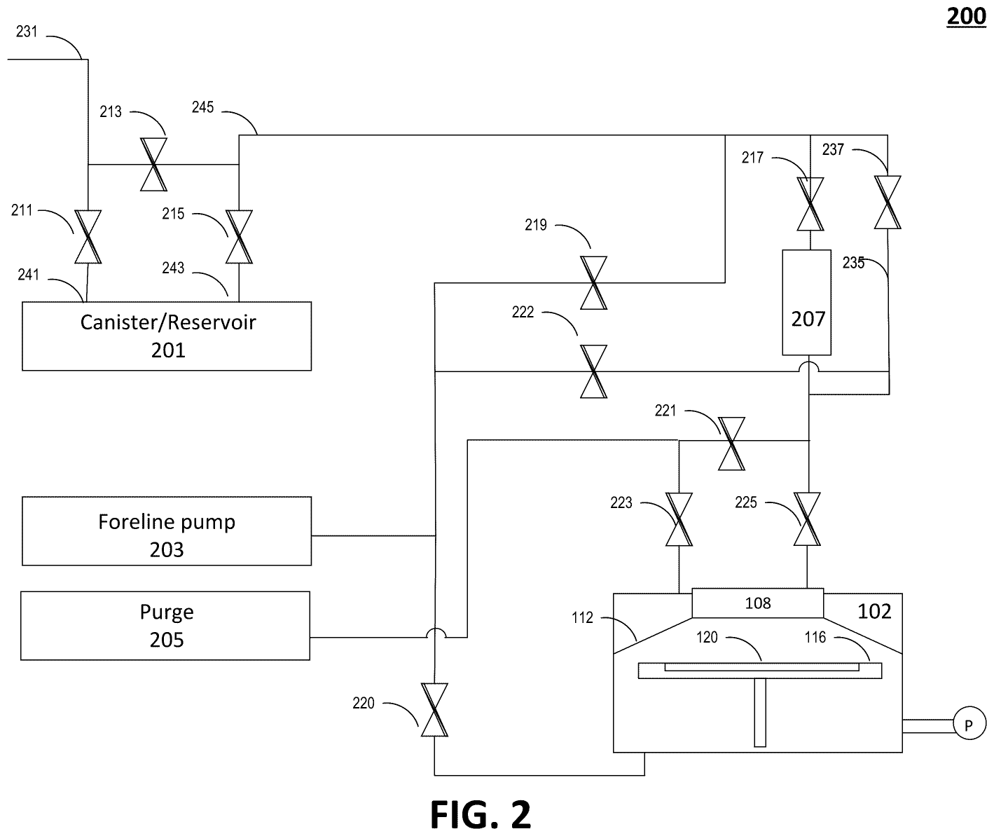

FIG. 2 schematically illustrates an exemplary precursor delivery system 200 with a filter and a bypass line according to some embodiments. For clarity, the illustrated precursor delivery system 200 includes one precursor source. However, it will be understood that in various embodiments, the thin film deposition system 200 may comprise any suitable number of precursor sources. In the embodiment illustrated in FIG. 2, the precursor delivery system 200 comprises a precursor canister or reservoir 201 that may be configured for delivery of liquid or solid precursor, or even gaseous precursor. In some embodiments, the precursor delivery system 200 further comprises a foreline pump 203, a purge gas source 205, a filter 207, a bypass line 235, and valves 211, 213, 215, 217, 219, 220, 221, 222, 223, 225, 237. Any or all of the valves may be an ALD valve.

As configured in FIG. 2, the precursor delivery system 200 includes a selective filtration portion comprising two parallel branches branching out from the gas line 245. The two parallel branches include a first branch branching from the gas line 245 and connected to a filter 207 and accessed via a first valve 217. The filter 207 may also be connected to a deposition chamber 102. The two parallel branches include a second branch branching from the gas line 245, which is illustrated as a bypass line 235 that is accessed via a second valve 237. The bypass line 235 may in turn be connected to the deposition chamber 102. In operation, as shown in FIG. 2, a precursor source may be delivered by passing a carrier gas through the precursor canister/reservoir 201 through gas line 231 and the valve 211 when the valve 211 is opened. The liquid or solid precursor in the canister 201 can be heated to a suitable temperature such that the carrier gas flowing into the precursor canister/reservoir 201 can carry the evaporated or sublimated precursor out from the canister 201. The carrier gas and/or precursor gas may flow out of the precursor canister/reservoir 201 through valve 215 into gas line 235 when the valve 215 is opened. The carrier gas and/or precursor gas may flow from gas line 245 through valve 217 into filter 207 when the valve 217 is opened. The carrier gas and/or precursor gas may also flow from gas line 245 through valve 237 into the bypass line 235 when the valve 237 is opened. The carrier gas and/or precursor gas may enter the deposition chamber 102 either from the filter 207 or the bypass line 235 when the valve 225 is opened. The purge source 205 may be connected to the chamber 102 through valve 223 and filter 207 and bypass line 235 through valve 221. The foreline pump 203 may be in connection with filter 207 through valve 219 and valve 217. The foreline pump 203 may be also in connection with the bypass line 235 through the valve 219 and 237. The foreline pump 203 may be in connection with the bypass line 235 through valve 222. The foreline pump 203 may be in connection with the chamber 102 through valve 220.

### 1. Precursor Delivery Line During Production and Line Purging Process

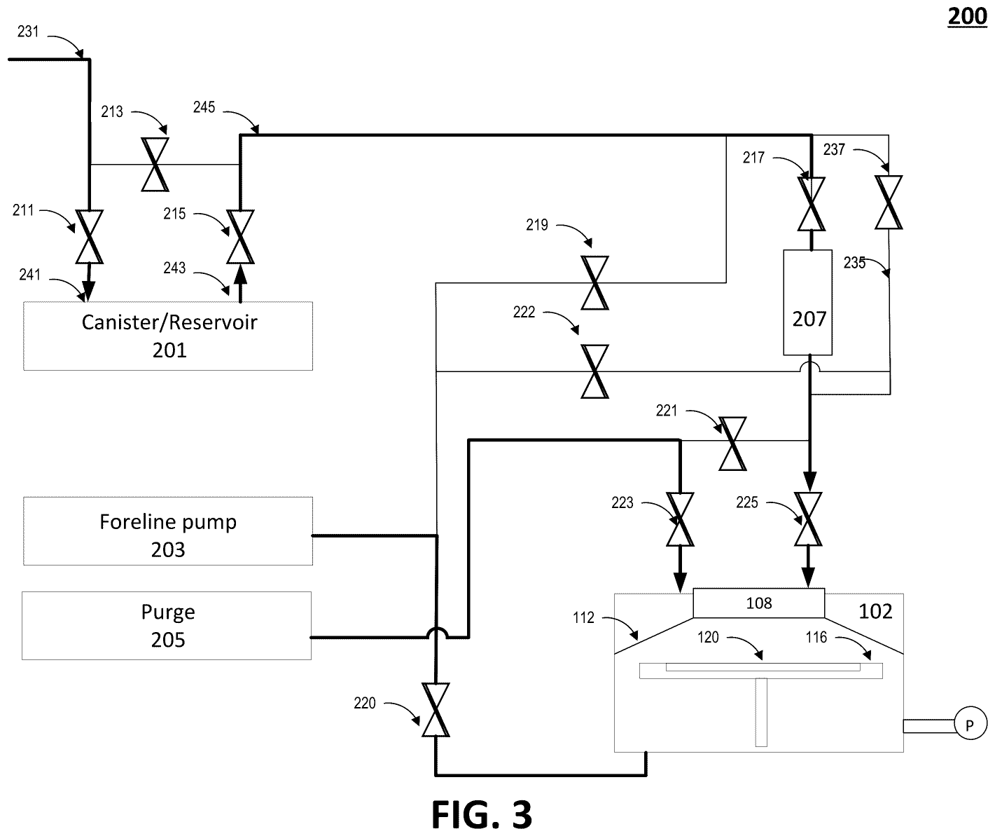

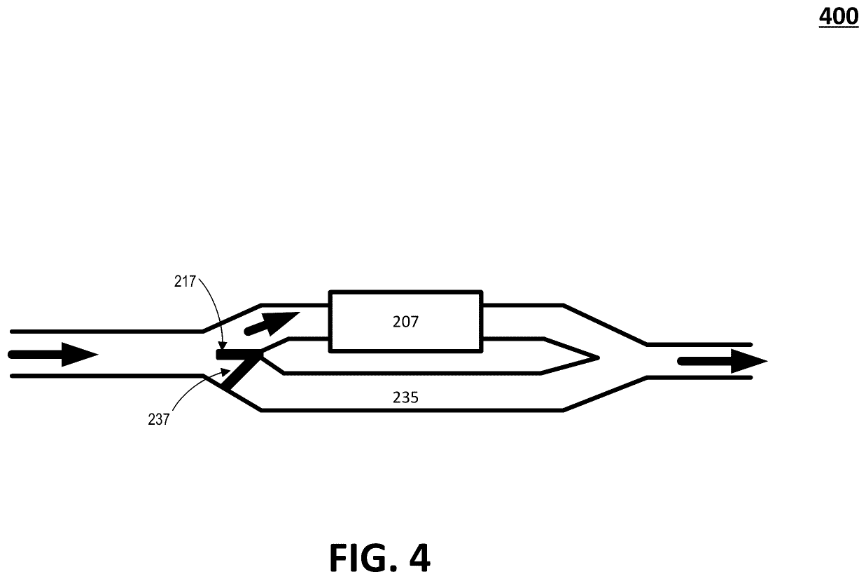

As described above, in some embodiments, e.g., when the precursor source is a liquid or solid source, a carrier gas may carry an evaporated or sublimated precursor as it passes through a precursor canister. According to various embodiments, the carrier gas carrying the precursor may enter the deposition chamber after being filtered by a filter. The filter may remove unwanted impurities and particle defects, such as precursor clusters, particle condensates, from the precursor gas, such that the quality of the deposited film may be improved. However, as described above, when the precursor delivery line is not actively delivering the vaporized precursor, e.g., when the precursor delivery line is being purged or cleaned, it may be advantageous to bypass the filter to prolong the lifetime of the filter. Exemplary FIGS. 3 and 4 schematically illustrate the precursor delivery system 200 in use to illustrate these processes according to some embodiments.

FIG. 3 schematically illustrates the precursor delivery system 200 with filter and bypass line when the precursor delivery line is actively delivering the precursor into the chamber, e.g., during production, according to some embodiments. As illustrated in FIG. 3, the bolded gas lines represent that a gas may pass through. During production, in some embodiments, in the step of exposing the substrate to a precursor, valves 211, 215, 217, 220, and 225 are open, and valves 213, 237, 219, 221 and 222 are closed. In some embodiments, in the step of exposing the substrate to a precursor, the valve 220 is open. In some embodiments, in the step of exposing the substrate to a precursor, the valve 220 is closed. In those embodiments, the carrier gas may enter into the canister/reservoir 201 through the gas inlet 241, and the carrier gas carrying the precursor may flow out of the canister/reservoir 201 through the gas outlet 243. As the valve 217 is open and valve 237 is closed, the carrier gas carrying the precursor passes through the filter 207 and is not bypassed through the bypass line 235. After being filtered by the filter 207, the carrier gas carrying the precursor enters the chamber through the opened valve 225. In some embodiments, a purge gas may be continuously supplied into the chamber from the purge source 205 through the valve 223 during the production. In some embodiments, valve 220 is open and the foreline pump 203 is connected to the chamber and is in operation throughout the production.

FIG. 4 schematically illustrates the filter and the bypass line when the precursor delivery line is actively delivering the precursor into the chamber, e.g., during the production according to some embodiments. As shown in FIG. 4, in some embodiments, during production, the valve 217 is opened and the valve 237 is closed, such that the carrier gas and the precursor gas flow from the gas line into the filter 207 through the valve 217 and cannot enter the bypass line 235 through the valve 237. After being filtered by the filter 207, the precursor and carrier gas may flow towards the chamber 102. Filtering the precursor gas may remove unwanted impurities and particle defects, such as precursor clusters, particle condensates, from the precursor gas. This filtering may reduce the overall number of defects within a deposited film.

In another embodiment, in the step of exposing the substrate to a precursor, the precursor may be supplied through the bypass line 235 rather than through the filter 207. In those embodiments, the valves 211, 215, 237, 220, and 225 are open, and valves 213, 217, 219, 221 and 222 are closed. In some embodiments, in the step of exposing the substrate to a precursor, the valve 220 is open. In some other embodiments, in the step of exposing the substrate to a precursor, the valve 220 is closed. In some embodiments, when the precursor is initially supplied into the precursor delivery system (i.e., during “burp”), the precursor is supplied through the bypass line 235 instead of the filter 207.

In some embodiments, a purge gas may be supplied into the chamber from the purge source 205 after a precursor is provided to remove excess precursor or to clean out the precursor delivery line. In some embodiments, a purge gas may be supplied into the chamber from the purge gas source 205 throughout the production process. In some embodiments, a carrier gas may be supplied into the deposition chamber without a precursor gas during the purge process. In some embodiments, a carrier gas may be supplied through the gas line into the deposition chamber to clean the gas line without carrying a precursor gas. In those embodiments, the carrier gas may pass through the bypass line rather than through the filter since there is no precursor gas needs to be filtered. Thus, the lifetime of the filter may be prolonged for more cycles.

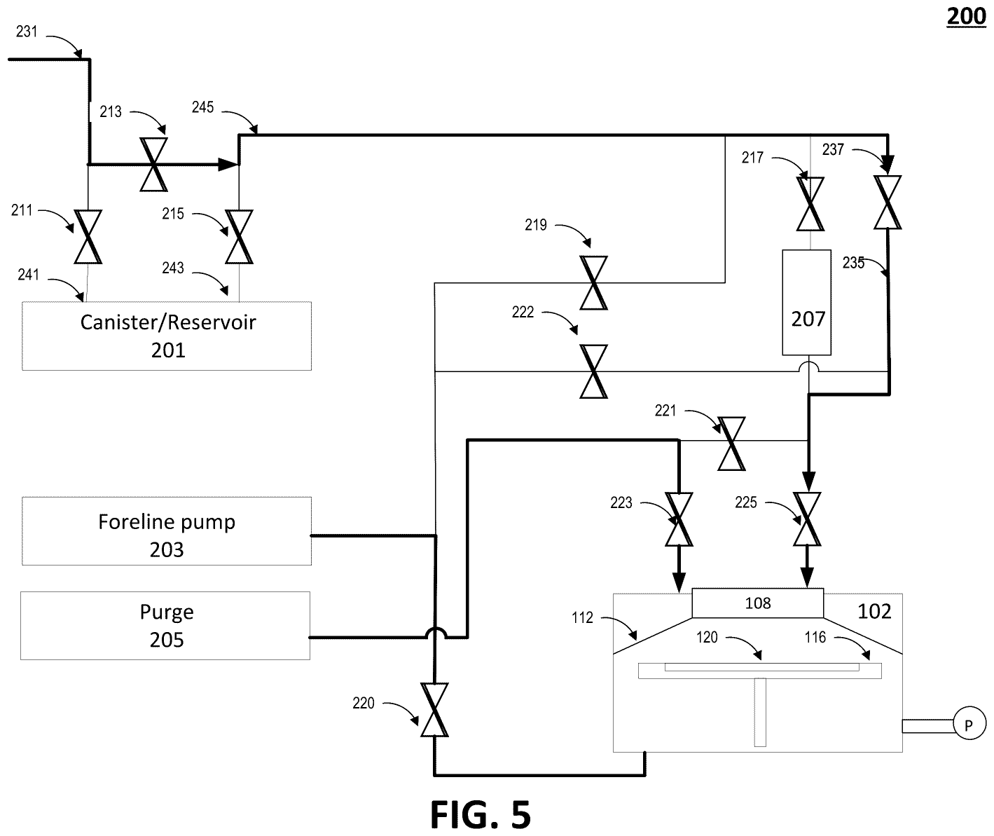

FIG. 5 schematically illustrates a precursor delivery system 200 with the filter 207 and the bypass line 235 during a gas cleaning process according to some embodiments. As illustrated in FIG. 5, the bolded gas lines represent that a gas may pass through. In some embodiments, during a purge process or gas cleaning process, the valves 213, 220, 223, 225 and 237 are open, and the valves 211, 215, 217 and 221 are closed. In those embodiments, the carrier gas may not enter into the canister/reservoir 201 may flow through the valve 213 into the gas line 245. As the valve 237 is open and the valve 217 is closed, the carrier gas may pass through the bypass line 237 and not enter the filter 207. In some embodiments, a purge gas may be supplied into the chamber 102 from purge gas source 205. In some embodiments, the purge gas or carrier gas entered into the chamber 103 may be evacuated by the foreline pump 203 through valve 220. In some embodiments, the valve 222 is open and the carrier gas may be evacuated through the valve 222 by the foreline pump 203 after cleaning the gaslines and the bypass line before entering the chamber. In some embodiments, the valve 222 is closed during the gas line cleaning or purge process. In some embodiments, the valve 219 is closed during the gas line cleaning or purge process.

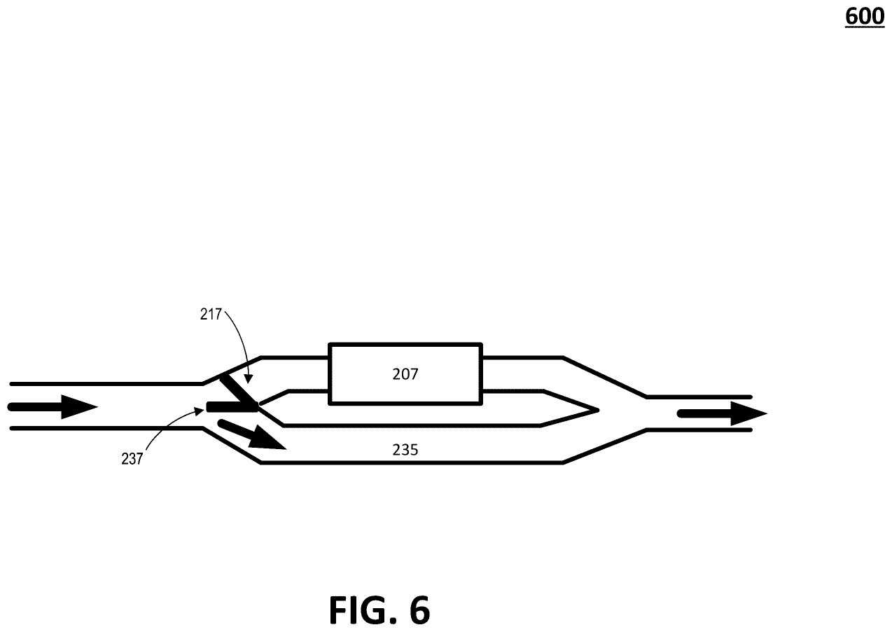

FIG. 6 schematically illustrates the filter and the bypass line during the gas line cleaning process according to some embodiments. As shown in FIG. 6, in some embodiments, during the gas line cleaning process, the valve 217 is closed and the valve 237 is opened, such that the carrier gas flow from the gas line into the bypass line 245 through valve 237 and cannot enter the filter 207 through valve 217. The carrier gas may flow towards the chamber 102 or foreline pump 203 without being filtered since there is no precursor gas with the carrier gas.

### 2. Precursor Delivery Line During Filter Cleaning Process

In some embodiments, after the precursor has been flowed into the deposition chamber through the filter for a certain number of cycles or a certain amount of time, the filter may be clogged by the precursor clusters, precursor condensates, impurities, and other contaminations. The contaminations may attach to the pores of the filter and the productivity of the filter may be decreased. For example, the pressure may shift, the dosage may drop, which may result in wafer-wafer variations. In some embodiments, a filter cleaning may be performed to prolong the lifetime of the filter. In addition, by prolonging the lifetime of the filter, a filter lifetime may be matched to a scheduled maintenance time for opening the deposition chamber.

In some embodiments, the filter cleaning process may comprise supplying a purge gas through the filter 207. In some embodiments, the filter 207 may be directional. In some embodiments, the filter 207 may only filter the gas flowing in one direction. In some embodiments, the filter 207 may only filter the gas flowing from gas line 245 to the chamber 102. In some embodiments, supplying a purge gas to clean the filter 207 may comprise pumping a purge gas in the opposite direction of the filter 207. In some embodiments, pumping a purge gas through the filter 207 may remove particles that are embedded within the filter 207. In some embodiments, removing particles embedded within the filter 207 may clean the filter and improve the lifetime of the filter. In some embodiments, the filter cleaning process may further comprise heating the filter when supplying a purge gas through the filter 207.

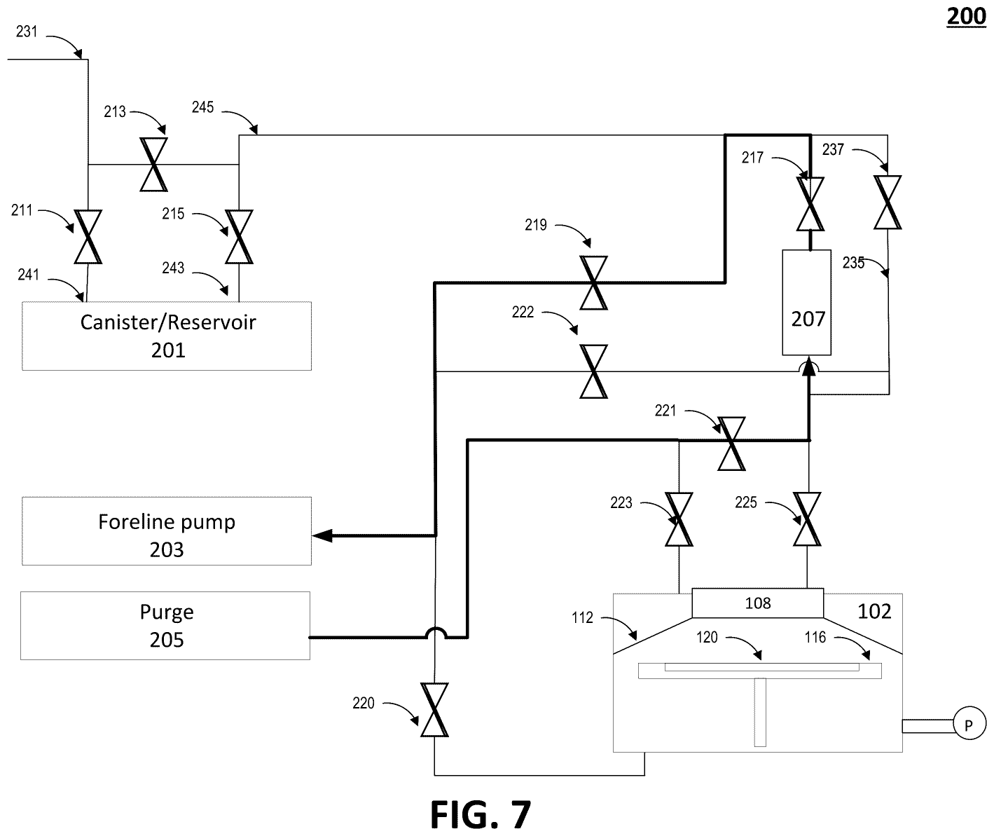

FIG. 7 schematically illustrates a method for cleaning a filter according to some embodiments. As illustrated in FIG. 7, the bolded gas lines represent that a gas may pass through. In some embodiments, a purge gas may be pumped from a purge gas source 205 through the filter 207 by foreline pump 203. In some embodiments, the direction of the filter 207 may be from valve 217 towards the chamber. In some embodiments, the filter 207 may filter precursors flow from canister/reservoir 201 towards the chamber 102. In some embodiments, during a filter cleaning process, the valves 217, 219 and 221 are open, and the valves 211, 213, 215, 222, 223, 225 and 227 are closed. In some embodiments, the valve 220 is open. In some embodiments, the valve 220 is closed. In some embodiments, a foreline pump 203 may be connected to filter 207 through valves 219 and 217. In those embodiments, during filter cleaning process, no carrier gas or precursor gas may be supplied into the chamber 102. In some embodiments, during the filter cleaning process, the foreline pump 203 may pump the purge gas from the purge source 205 through the filter in the opposite direction of the filter when in normal use. In some embodiments, pumping a purge gas through the filter 207 may remove particles that are embedded within the filter 207. In some embodiments, removing particles embedded within the filter 207 may clean the filter and improve the lifetime of the filter.

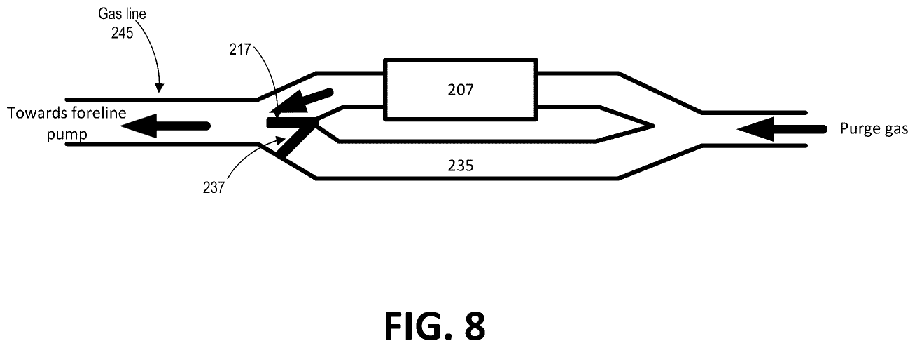

FIG. 8 schematically illustrates the filter and the bypass line during the filter cleaning process according to some other embodiments. In some embodiments, the foreline pump may be connected to the gas line 245. In those embodiments, during the filter cleaning process, no carrier gas or precursor gas may be supplied through the filter 207. As shown in FIG. 8, the valve 217 may be opened and the valve 237 may be closed, such that the gas may only pass through valve 217 and may not pass through valve 237. In some embodiments, a purge gas may be pumped through the filter 207 by a foreline pump connected to the gas line 245. In some embodiments, the filter 207 may filter precursors flow from the precursor source towards the chamber. In some embodiments, pumping a purge gas through the filter 207 may remove particles that are embedded within the filter 207. In some embodiments, removing particles embedded within the filter 207 may clean the filter and improve the lifetime of the filter.

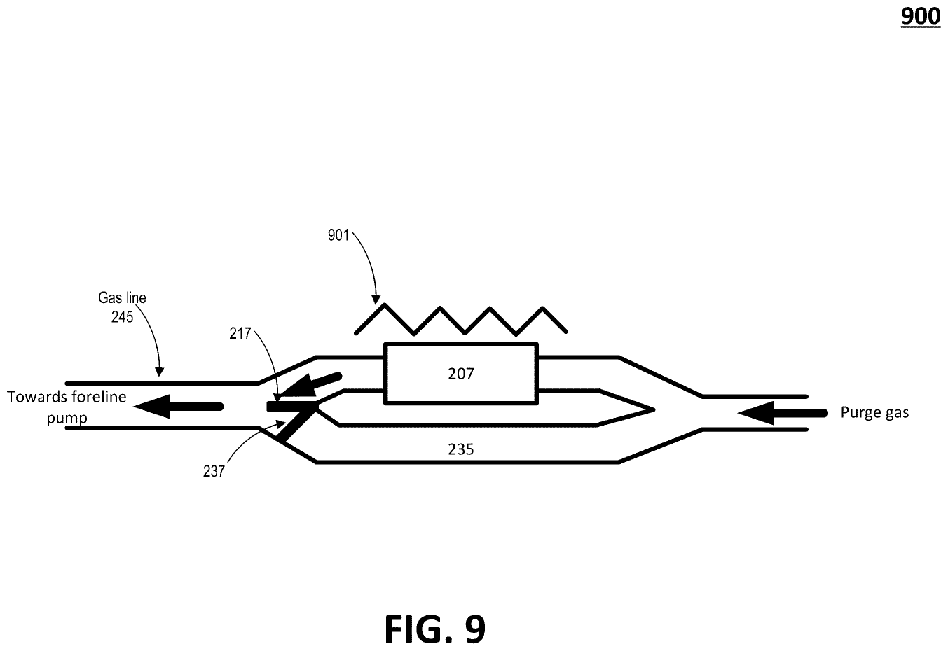

FIG. 9 schematically illustrates another method of cleaning a filter according to some embodiments.

In some embodiments, the precursor delivery line may further comprise a heating element 901. In some embodiments, the filter 207 may be connected or surrounded by the heating elements 901. In some embodiments, the filter 207 may only filter the gas to flowing in one direction. In some embodiments, the filter 207 may only filter the gas flowing from gas line 245 to the chamber 102. In some embodiments, during the cleaning, the valve 217 may be opened and the valve 237 may be closed. In some embodiments, during the filter cleaning process, the heating element 901 may be configured to heat the filter 207. In some embodiments, during the filter cleaning process, the filter 207 is heated by the heating element 901 while a purge gas is pumped through the filter 207 by a foreline pump connected to the gas line 245. Not to be bound by the theory, heating the filter 207 may loosen some of the particles embedded within the pores of the filter 207. Heating the filter 207 may help vaporize the precursor particles or condensations. Moreover, heating the filter 207 may decrease the size of the precursor clusters, precursor condensates, impurities, or other contaminations being filtered by and attached to the filter 207 when the precursor passes through the filter 207 into the chamber 102. Since the size of the precursor clusters precursor condensates, impurities, or other contaminations is decreased, the particles may pass through the filter and the filter cleaning efficiency may be enhanced. In some embodiments, during the filter cleaning process, a purge gas may be pumped by the foreline pump through the filter 207. In some embodiments, pumping a purge gas through the filter 207 may remove particles that are embedded within the filter 207. In some embodiments, heating the filter 207 may allow quicker and more efficient removal of the particles embedded in the pores of the filter 207 comparing to not heating the filter 207. In some embodiments, removing particles embedded within the pores of the filter 207 may clean the filter 207 and improve the lifetime of the filter.

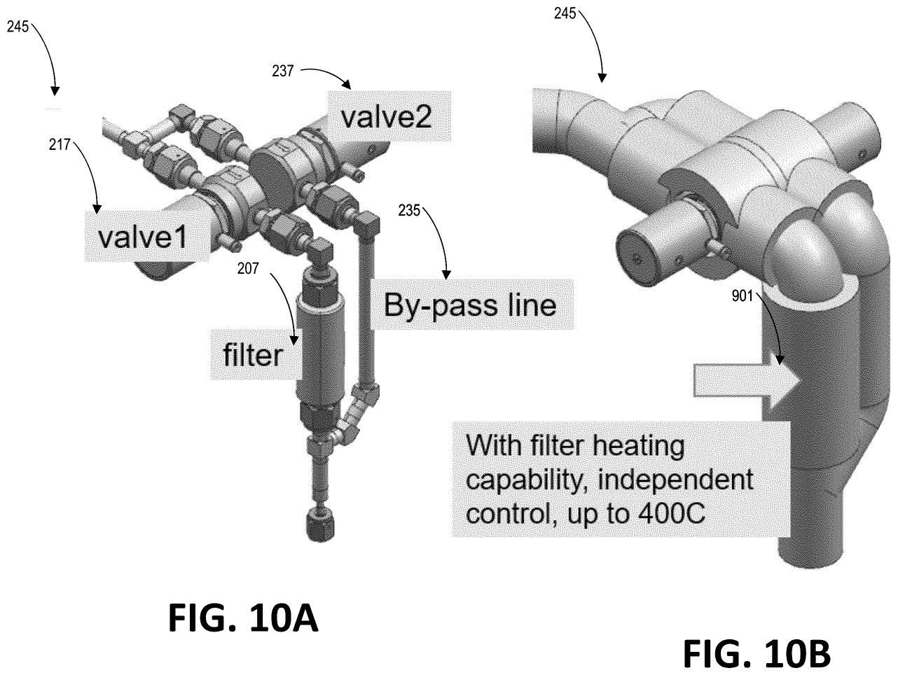

FIG. 10A shows a three-dimensional illustration of a precursor delivery line without heating element according to some embodiments. As illustrated in FIG. 10A, in some embodiments, a gas line 245 may be connected to a first valve 217 and a second valve 237. The first valve 217 may be connected to or in fluid connection with a filter 207. The second valve 237 may be connected to or in fluid connection with a bypass line 235. Both the filter 207 and the bypass line 235 may be connected to or in fluid connection with a reactor chamber (not pictured) via a gas line.

FIG. 10B shows a three-dimensional illustration of a precursor delivery system with a heating element according to some embodiments. As illustrated in FIG. 10B, the filter 207 may be surrounded by or connected to a heating element 901. The heating element 901 may be configured to heat the filter 207. In some embodiments, the heating clement 901 may heat the filter 207 to about 50° C., about 100° C., about 150° C., about 200° C., about 250° C., about 300° C., about 350° C., about 400° C., about 450° C., about 500° C., or any range of values between those values. In some embodiments, the heating element 901 may be independently controlled. In some embodiments, the heating element 919 may be precisely controlled to heat the filter 207 to any temperature below about 500° C.

Advantageously, the lifetime of the filter 207 may be extended after the filter cleaning process. In some embodiments, the lifetime of the filter 207 may be extended to match the lifetime of a source, precursor canister, or chamber condition such as process kit, such that the tool up time may be optimized.

In some embodiments, the filter has a filtration zone having a filtration size of about 2 nm, 3 nm, 4 nm, 5 nm, 6 nm, 7 nm, 8 nm, 9 nm, 10 nm, 11nm, 12 nm, 13 nm, 14 nm, 15 nm, 16 nm, 17 nm, 18 nm, 19 nm, 20 nm, 25 nm, 30 nm, 35 nm, 40 nm, 45 nm, 50 nm, or any range of values between those values. In some embodiments, the filtration size of the filtration zone depends on the size of the precursor. In some embodiments, the filtration size is about 2, 3, 4, 5, 6, 7, 8, 9, 10, 15, 20, 25, 30, 35, 40, 45, 50 times of the size of the precursor molecules, or any range of values between those values. In some embodiments, the precursor has a size of about 1 nm and the filtration zone has a filtration size of about 10 nm. In some embodiments, the filtration zone is configured to capture particles having an average size larger than about 2 nm, 3 nm, 4 nm, 5 nm, 6 nm, 7 nm, 8 nm, 9 nm, 10 nm, 11 nm, 12 nm, 13 nm, 14 nm, 15 nm, 16 nm, 17 nm, 18 nm, 19 nm, 20 nm, 25 nm, 30 nm, 35 nm, 40 nm, 45 nm, 50 nm, or any range of values therebetween.

In some embodiments, the filter 207 may be periodically cleaned and reused. The periodic cleaning of the filter may not be dependent on the condition of the filter, thus there may not be a need to assess the condition of the filter. In some embodiments, such periodic cleaning may be carried out based on the number of deposition cycles. In some embodiment, the periodic cleaning is carried out after 100, 200, 500, 800, 1000, 1500, 2000, 2500, 3000, 3500, 4000, 4500, 5000, 6000, 7000, 8000, 9000, 10000, 15000, 20000, 50000, 10000 cycles, or any number of cycles in a range defined by any of these values. In some embodiment, the number of cycles is determined by a person skilled in the art based on the needs and the process conditions. In some embodiments, such periodic cleaning may be carried out based on the number of wafers processed in the reaction chamber. In some embodiment, the periodic cleaning is carried out after the deposition on 2, 5, 10, 20, 50, 80, 100, 150, 200, 250, 300, 350, 400, 450, 500, 600, 700, 800, 900, 1000, 1500, 2000, 5000, 1000 wafers, or any number of wafers in a range defined by any of these values. In some embodiments, the number of wafers is determined by a person skilled in the art based on the needs and process conditions. In some embodiments, the cleaning method of the periodic cleaning is similar to the cleaning methods described above. Such periodic cleaning of a filter could increase the lifetime and performance of the filter.

### Additional Examples

1. A precursor delivery system for depositing a thin film in a thin film deposition chamber, the precursor delivery system comprising:
   a precursor delivery line comprising a selective filtration portion configured to flow a precursor therethrough,
   wherein the selective filtration portion is configured to selectively capture particles contained in the precursor flowing therethrough while bypassing gases other than the precursor flowing therethrough.
2. The precursor delivery system of Example 1, wherein the selective filtration portion comprises two parallel branches splitting from an inlet and remerging into an outlet connected to the thin film deposition chamber, and wherein one but not the other of the two parallel branches comprises a particle filtration zone configured to capture particles contained in a gas flowing therethrough.
3. The precursor delivery system of Example 2, wherein one of the two parallel branches is configured to selectively flow a precursor through a particle filtration zone, while the other of the two parallel branches is configured to selectively flow an inert gas.
4. The precursor delivery system of Example 2 or Example 3, wherein the particle filtration zone is configured to capture particles contained in a gas flowing therethrough in a first flow direction, and wherein the precursor delivery system further comprises a purge gas delivery line configured to flow a purge gas through the particle filtration zone in a second flow direction opposite the first flow direction to at least partly release the particles captured in the particle filtration zone.
5. The precursor delivery system of any one of Examples 2-4, wherein the particle filtration zone is configured to be heated to at least partly release the particles captured in the particle filtration zone.
6. A precursor delivery system for depositing a thin film in a thin film deposition chamber, the precursor delivery system comprising:
   a precursor delivery line comprising a selective filtration portion; and
   the selective filtration portion comprising two parallel branches splitting from an inlet and remerging into an outlet connected to the thin film deposition chamber,
   wherein one but not the other of the two parallel branches comprises a particle filtration zone configured to capture particles contained in a precursor flowing therethrough.
7. The precursor delivery system of Example 6, wherein the selective filtration portion is configured to selectively capture particles contained in the precursor flowing therethrough while bypassing gases other than the precursor flowing therethrough.
8. The precursor delivery system of Example 6 or Example 7, wherein one of the two parallel branches is configured to selectively flow the precursor through a particle filtration zone, while the other of the two parallel branches is configured to selectively flow an inert gas,
9. The precursor delivery system of any one of Examples 6-8, wherein the particle filtration zone is configured to capture particles contained in the precursor flowing therethrough in a first flow direction, and wherein the precursor delivery system further comprises a purge gas delivery line configured to flow a purge gas through the particle filtration zone in a second flow direction opposite the first flow direction to at least partly release the particles captured in the particle filtration zone.
10. The precursor delivery system of any one of Example 6-9, wherein the particle filtration zone is configured to be heated to at least partly release the particles captured in the particle filtration zone.
11. A precursor delivery system for a thin film deposition system, the precursor delivery system comprising:
a precursor delivery line comprising a selective filtration portion; and
the selective filtration portion comprising two parallel branches,
wherein one of the two parallel branches is configured to selectively flow a precursor through a particle filtration zone, while the other of the two parallel branches is configured to selectively flow an inert gas.
12. The precursor delivery system of Example 11, wherein the selective filtration portion is configured to selectively capture particles contained in the precursor flowing therethrough while bypassing gases other than the precursor flowing therethrough.
13. The precursor delivery system of Example 11 or Example 12, wherein the selective filtration portion comprises two parallel branches splitting from an inlet and remerging into an outlet connected to the thin film deposition system, and wherein one but not the other of the two parallel branches comprises a particle filtration zone configured to capture particles contained in a gas flowing therethrough,
14. The precursor delivery system of any one of Examples 11-13, wherein the particle filtration zone is configured to capture particles contained in a gas flowing therethrough in a first flow direction, and wherein the precursor delivery system further comprises a purge gas delivery line configured to flow a purge gas through the particle filtration zone in a second flow direction opposite the first flow direction to at least partly release the particles captured in the particle filtration zone.
15. The precursor delivery system of any one of Examples 11-14, wherein the particle filtration zone is configured to be heated to at least partly release the particles captured in the particle filtration zone.
16. A precursor delivery system for depositing a thin film in a thin film deposition chamber, the precursor delivery system comprising:
   a precursor delivery line comprising a selective filtration portion;
   the selective filtration portion comprising a particle filtration zone configured to capture particles contained in a gas flowing therethrough in a first flow direction; and
   a purge gas delivery line configured to flow a purge gas through the particle filtration zone in a second flow direction opposite the first flow direction to at least partly release the particles captured in the particle filtration zone.
17. The precursor delivery system of Example 16, wherein the selective filtration portion is configured to selectively capture particles contained in the precursor flowing therethrough while bypassing gases other than the precursor flowing therethrough.
18. The precursor delivery system of Example 16 or Example 17, wherein the selective filtration portion comprises two parallel branches splitting from an inlet and remerging into an outlet connected to the thin film deposition chamber, and wherein one but not the other of the two parallel branches comprises a particle filtration zone configured to capture particles contained in a gas flowing therethrough.
19. The precursor delivery system of any one of Examples 16-18, wherein one of the two parallel branches is configured to selectively flow a precursor through a particle filtration zone, while the other of the two parallel branches is configured to selectively flow an inert gas.
20. The precursor delivery system of any one of Examples 16-19, wherein the particle filtration zone is configured to be heated to at least partly release the particles captured in the particle filtration zone.
21. A precursor delivery system for depositing a thin film in a thin film deposition chamber, the precursor delivery system comprising:
   a precursor delivery line comprising a selective filtration portion; and
   the selective filtration portion comprising a particle filtration zone configured to capture particles contained in a gas flowing therethrough,
   wherein the particle filtration zone is configured to be heated to at least partly release the particles captured in the particle filtration zone.
22. The precursor delivery system of Example 21, wherein the selective filtration portion is configured to selectively capture particles contained in the precursor flowing therethrough while bypassing gases other than the precursor flowing therethrough.
23. The precursor delivery system of Example 21 or Example 22, wherein the selective filtration portion comprises two parallel branches splitting from an inlet and remerging into an outlet connected to the thin film deposition chamber, and wherein one but not the other of the two parallel branches comprises a particle filtration zone configured to capture particles contained in a gas flowing therethrough.
24. The precursor delivery system of any one of Examples 21-23, wherein one of the two parallel branches is configured to selectively flow a precursor through a particle filtration zone, while the other of the two parallel branches is configured to selectively flow an inert gas.
25. The precursor delivery system of any one of Examples 21-24, wherein the particle filtration zone is configured to capture particles contained in a gas flowing therethrough in a first flow direction, and wherein the precursor delivery system further comprises a purge gas delivery line configured to flow a purge gas through the particle filtration zone in a second flow direction opposite the first flow direction to at least partly release the particles captured in the particle filtration zone.
26. The precursor delivery system of any one of the above Examples, wherein the particle filtration zone comprises two parallel branches comprising a particle filtration branch comprising the particle filtration zone and a bypass branch.
27. The precursor delivery system of any one of the above Examples, wherein the particle filtration zone is configured to capture particles having an average size larger than about 30 nm.
28. The precursor delivery system of any one of the above Examples, wherein the precursor delivery line is configured to flow into the thin film deposition chamber one or the other of a precursor and a carrier gas at a given time.
29. The precursor delivery system of any one of the above Examples, wherein each of two parallel branches comprises a valve, wherein one but not the other of the valve of the two parallel branches is configured to be open at a given time.
30. The precursor delivery system of any one of the above Examples, wherein the precursor delivery system is connected to the thin film deposition configured to deposit the thin film by alternatingly exposing a substrate to a plurality of precursors.
31. A thin film deposition system, comprising:
   a thin film deposition chamber configured to deposit a thin film;
   a precursor delivery system according to any one of the above Examples comprising the precursor delivery line connected to a precursor source and comprising the selective filtration portion comprising a filter.
32. The thin film deposition system of Example 31, wherein the selective filtration portion is configured to selectively capture the particles contained in the precursor flowing therethrough in a filter direction corresponding to a direction of the precursor through the filter when the precursor flows from the precursor source to the thin film deposition chamber.
33. The thin film deposition system of Example 31 or Example 32, wherein the precursor delivery line further comprises a first valve connecting the precursor source to the filter and a second valve connecting the precursor source to the bypass line.
34. The thin film deposition system of Example 33, wherein the first valve is configured to be opened and the second valve is configured to be closed when the precursor from the precursor source is supplied to the thin film deposition chamber.
35. The thin film deposition system of Example 34, wherein the filter is configured to filter the precursor before entering the thin film deposition chamber.
36. The thin film deposition system of any one of Examples 33-35, wherein the first valve is configured to be closed and the second valve is configured to be opened when a carrier gas without the precursor is supplied into the thin film deposition chamber.
37. The thin film deposition system of Example 36, wherein the carrier gas is configured to flow through the bypass line while not being configured to flow through the filter before entering the thin film deposition chamber.
38. The thin film deposition system of any one of Examples 32-37, further comprising a vacuum pump configured to pump a purge gas from a purge gas source through the filter in a direction opposite to the filter direction during a filter cleaning process.
39. The thin film deposition system of Example 38, wherein during the filter cleaning process, the first valve is configured to be opened and the second valve is configured to be closed.
40. The thin film deposition system of Example 38 or Example 39, further comprising a heating element configured to heat the filter during the filter cleaning process.
41. The thin film deposition system of Example 40, wherein the heating element surrounds the filter.
42. The thin film deposition system of Example 40 or Example 41, wherein the heating element is configured to heat the filter up to about 400° C.
43. The thin film deposition system of any one of Examples 31-43, wherein the thin film deposition chamber is configured to deposit a thin film by alternatingly exposing a substrate to a plurality of precursors.
44. A method of depositing a thin film, the method comprising:
   providing a thin film deposition system comprising a thin film deposition chamber and a precursor delivery system according to any one of Examples 1-30, wherein the selective filtration zone of the precursor delivery line comprises two parallel branches comprising a particle filtration branch comprising a particle filtration zone, access to which is controlled by a first valve, and a bypass branch, access to which is controlled by a second valve; and
   exposing a substrate in the thin film deposition chamber to a precursor by opening the first valve while the second valve is closed, such that the precursor flows selectively through the particle filtration branch.
45. The method of Example 44, further comprising, before or after exposing the substrate to the precursor in the thin film deposition chamber, purging the precursor delivery line by closing the first valve and opening the second valve and flowing an inert gas selectively through the bypass branch.
46. The method of Example 45, wherein at least some particles in the precursor are filtered in the particle filtration zone, prior to exposing the substrate to the precursor in the thin film deposition chamber.
47. The method of Example 45 or Example 46, wherein the inert gas is not filtered in the particle filtration zone being flown into the thin film deposition chamber.
48. A method of cleaning a filter in a precursor delivery system for thin film deposition, the method comprising:
   providing a thin film deposition system comprising a thin film deposition chamber and a precursor delivery system according to any one of Examples 1-30, wherein the particle filtration zone of the selective filtration portion is configured to capture particles contained in a gas flowing therethrough in a first flow direction; and
   flowing a purge gas though the particle filtration zone in a second flow direction opposite to the first flow direction to at least partly release the particles captured in the particle filtration zone.
49. The method of Example 48, further comprising heating the particle filtration zone to at least partly release the particles captured in the particle filtration zone.
50. The method of Example 49, wherein heating comprises heating to a temperature greater than room temperature and up to about 400° C.
51. The method of Example 50, wherein the first flow direction is a flow direction of the precursor from a precursor source to the thin film deposition chamber.
52. A method of depositing a thin film, the method comprising:
   providing a thin film deposition system comprising a thin film deposition chamber and a precursor delivery system comprising a precursor delivery line having a selective filtration portion, wherein the selective filtration portion of the precursor delivery line comprises two parallel branches comprising a particle filtration branch comprising a particle filtration zone, access to which is controlled by a first valve, and a bypass branch, access to which is controlled by a second valve; and
   exposing a substrate in the thin film deposition chamber to a precursor by opening the first valve while the second valve is closed, such that the precursor flows selectively through the particle filtration branch.
53. The method of Example 52, further comprising, before or after exposing the substrate to the precursor in the thin film deposition chamber, purging the precursor delivery line by closing the first valve and opening the second valve and flowing an inert gas selectively through the bypass branch.
54. The method of Example 53, wherein at least some particles in the precursor are filtered in the particle filtration zone, prior to exposing the substrate to the precursor in the thin film deposition chamber.
55. The method of Example 53 or Example 54, wherein the inert gas is not filtered in the particle filtration zone being flown into the thin film deposition chamber.
56. A method of cleaning a filter in a precursor delivery system for thin film deposition, the method comprising:
   providing a thin film deposition system comprising a thin film deposition chamber and a precursor delivery system comprising a selective filtration portion having a particle filtration zone configured to capture particles contained in a gas flowing therethrough in a first flow direction; and
   flowing a purge gas though the particle filtration zone in a second flow direction opposite to the first flow direction to at least partly release the particles captured in the particle filtration zone.
57. The method of Example 56, further comprising heating the particle filtration zone to at least partly release the particles captured in the particle filtration zone.
58. The method of Example 57, wherein heating comprises heating to a temperature greater than room temperature and up to about 400° C.
59. The method of Example 58, wherein the first flow direction is a flow direction of the precursor from a precursor source to the thin film deposition chamber.

### Additional Considerations

Although the present invention has been described herein with reference to the specific embodiments, these embodiments do not serve to limit the invention and are set forth for illustrative purposes. It will be apparent to those skilled in the art that modifications and improvements can be made without departing from the spirit and scope of the invention.

Such simple modifications and improvements of the various embodiments disclosed herein are within the scope of the disclosed technology, and the specific scope of the disclosed technology will be additionally defined by the appended claims.

In the foregoing, it will be appreciated that any feature of any one of the embodiments can be combined or substituted with any other feature of any other one of the embodiments.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number, respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or whether these features, elements and/or states are included or are to be performed in any particular embodiment.

Language of degree used herein, such as the terms “approximately,” “about,” “generally,” and “substantially” as used herein represent a value, amount, or characteristic close to the stated value, amount, or characteristic that still performs a desired function or achieves a desired result. For example, the terms “approximately,” “about,” “generally,” and “substantially” may refer to an amount that is within less than 10% of, within less than 5% of, within less than 1% of, within less than 0.1% of, and within less than 0.01% of the stated amount, depending on the desired function or desired result.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while features are presented in a given arrangement, alternative embodiments may perform similar functionalities with different components and/or sensor topologies, and some features may be deleted, moved, added, subdivided, combined, and/or modified. Each of these features may be implemented in a variety of different ways. Any suitable combination of the elements and acts of the various embodiments described above can be combined to provide further embodiments. The various features and processes described above may be implemented independently of one another, or may be combined in various ways. All possible combinations and subcombinations of features of this disclosure are intended to fall within the scope of this disclosure.

What is claimed is:

1. A precursor delivery system for depositing a thin film in a thin film deposition chamber, the precursor delivery system comprising:
a precursor delivery line comprising a selective filtration portion configured to flow a precursor therethrough,
wherein the selective filtration portion is configured to selectively capture particles contained in the precursor flowing therethrough while bypassing gases other than the precursor flowing therethrough.

2. The precursor delivery system of claim 1, wherein the selective filtration portion comprises two parallel branches splitting from an inlet and remerging into an outlet connected to the thin film deposition chamber, and wherein one but not the other of the two parallel branches comprises a particle filtration zone configured to capture particles contained in a gas flowing therethrough.

3. The precursor delivery system of claim 2, wherein one of the two parallel branches is configured to selectively flow a precursor through a particle filtration zone, while the other of the two parallel branches is configured to selectively flow an inert gas.

4. The precursor delivery system of claim 2, wherein the particle filtration zone is configured to capture particles contained in a gas flowing therethrough in a first flow direction, and wherein the precursor delivery system further comprises a purge gas delivery line configured to flow a purge gas through the particle filtration zone in a second flow direction opposite the first flow direction to at least partly release the particles captured in the particle filtration zone.

5. The precursor delivery system of claim 2, wherein the particle filtration zone is configured to be heated to at least partly release the particles captured in the particle filtration zone.

6. A precursor delivery system for depositing a thin film in a thin film deposition chamber, the precursor delivery system comprising:
a precursor delivery line comprising a selective filtration portion; and
the selective filtration portion comprising two parallel branches splitting from an inlet and remerging into an outlet connected to the thin film deposition chamber,
wherein one but not the other of the two parallel branches comprises a particle filtration zone configured to capture particles contained in a precursor flowing therethrough.

7. The precursor delivery system of claim 6, wherein the selective filtration portion is configured to selectively capture particles contained in the precursor flowing therethrough while bypassing gases other than the precursor flowing therethrough.

8. The precursor delivery system of claim 6, wherein one of the two parallel branches is configured to selectively flow the precursor through the particle filtration zone, while the other of the two parallel branches is configured to selectively flow an inert gas.

9. The precursor delivery system of claim 6, wherein the particle filtration zone is configured to capture particles contained in the precursor flowing therethrough in a first flow direction, and wherein the precursor delivery system further comprises a purge gas delivery line configured to flow a purge gas through the particle filtration zone in a second flow direction opposite the first flow direction to at least partly release the particles captured in the particle filtration zone.

10. The precursor delivery system of claim 6, wherein the particle filtration zone is configured to be heated to at least partly release the particles captured in the particle filtration zone.

11. A precursor delivery system for a thin film deposition system, the precursor delivery system comprising:
a precursor delivery line comprising a selective filtration portion; and
the selective filtration portion comprising two parallel branches,
wherein one of the two parallel branches is configured to selectively flow a precursor through a particle filtration zone, while the other of the two parallel branches is configured to selectively flow an inert gas.

12. The precursor delivery system of claim 11, wherein the selective filtration portion is configured to selectively capture particles contained in the precursor flowing therethrough while bypassing gases other than the precursor flowing therethrough.

13. The precursor delivery system of claim 11, wherein the selective filtration portion comprises two parallel branches splitting from an inlet and remerging into an outlet connected to the thin film deposition system, and wherein one but not the other of the two parallel branches comprises the particle filtration zone configured to capture particles contained in a gas flowing therethrough.

14. The precursor delivery system of claim 11, wherein the particle filtration zone is configured to capture particles contained in a gas flowing therethrough in a first flow direction, and wherein the precursor delivery system further comprises a purge gas delivery line configured to flow a purge gas through the particle filtration zone in a second flow direction opposite the first flow direction to at least partly release the particles captured in the particle filtration zone.

15. The precursor delivery system of claim 11, wherein the particle filtration zone is configured to be heated to at least partly release particles captured in the particle filtration zone.

16. A precursor delivery system for depositing a thin film in a thin film deposition chamber, the precursor delivery system comprising:
a precursor delivery line comprising a selective filtration portion;
the selective filtration portion comprising a particle filtration zone configured to capture particles contained in a gas flowing therethrough in a first flow direction; and
a purge gas delivery line configured to flow a purge gas through the particle filtration zone in a second flow direction opposite the first flow direction to at least partly release the particles captured in the particle filtration zone.

17. The precursor delivery system of claim 16, wherein the selective filtration portion is configured to selectively capture particles contained in a precursor flowing therethrough while bypassing gases other than the precursor flowing therethrough.

18. The precursor delivery system of claim 16, wherein the selective filtration portion comprises two parallel branches splitting from an inlet and remerging into an outlet connected to the thin film deposition chamber, and wherein one but not the other of the two parallel branches comprises the particle filtration zone configured to capture the particles contained in the gas flowing therethrough.

19. The precursor delivery system of claim 18, wherein one of the two parallel branches is configured to selectively flow a precursor through the particle filtration zone, while the other of the two parallel branches is configured to selectively flow an inert gas.

20. The precursor delivery system of claim 16, wherein the particle filtration zone is configured to be heated to at least partly release the particles captured in the particle filtration zone.
